(19) United States
(12) Patent Application Publication
(10) Pub. No.: US 2025/0246215 A1
(43) Pub. Date: Jul. 31, 2025

(54) INTEGRATION OF MEMORY CELLS AND LOGIC CELLS FOR COMPUTE-IN-MEMORY APPLICATIONS

(71) Applicant: Taiwan Semiconductor Manufacturing Company, Ltd., Hsin-Chu (TW)

(72) Inventors: Chia He Chung, Hsinchu City (TW); Chih-Yung Lin, Hsinchu County (TW); Kuo-Hua Pan, Hsinchu City (TW); Chih-Hung Hsieh, Hsin-Chu (TW); Dian-Sheng Yu, Hsinchu City (TW)

(21) Appl. No.: 18/427,079

(22) Filed: Jan. 30, 2024

(51) Int. Cl. G11C 11/419; G11C 5/06; G11C 11/418; H01L 23/528; H10B 10/00

(52) U.S. Cl. CPC G11C 7/1006; G11C 5/063; G11C 11/418; H01L 23/528; H01L 23/5283; G11C 11/419; G11C 11/54; H10B 10/12

(57) ABSTRACT

A semiconductor structure includes a memory cell connected to a signal line, a first voltage line for receiving a power supply voltage, and a second voltage line for receiving an electric ground voltage, a logic cell configured to provide logic function to the memory cell, a transition region extending from a first boundary of the memory cell to a second boundary of the logic cell, and an interconnect structure disposed over the memory cell and the logic cell. The interconnect structure includes the signal line, the first voltage line, and the second voltage line located in a same metal line layer of the interconnect structure. The signal line extends from inside the second boundary of the logic cell and into the first boundary of the memory cell. The transition region includes one or more functional transistors electrically coupled to the memory cell.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Memories are commonly used in ICs. For example, a static random-access memory (SRAM) is a volatile memory used in electronic applications where high speed, low power consumption, and simplicity of operation are needed. Embedded SRAM is particularly popular in high-speed communications, image processing, and system-on-chip (SOC) applications. SRAM has the advantage of being able to hold data without requiring a refresh. As artificial intelligence (AI) has revolutionized present-day life through automation and independent decision-making capabilities, SRAM has become a suitable candidate for AI hardware implementations due to its performance edge over its counterparts. However, modern AI hardware such as neural networks (NNs) access off-chip data quite often, degrading the overall system performance. Compute-in-memory (CIM) architecture reduces off-chip data access transactions. An SRAM structure includes SRAM cells and logic cells. Although existing SRAM structures for memory-based ICs have been generally adequate for traditional memory applications, the integration of SRAM cells and logic cells have not been entirely satisfactory for CIM applications.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate block diagrams of a semiconductor device that includes a memory macro for compute-in-memory (CIM) applications, in accordance with some embodiments of the present disclosure.

FIG. 2 illustrates a circuit schematic for a single-port static random-access memory (SRAM) cell, in accordance with some embodiments of the present disclosure.

FIG. 3 illustrates a cross-sectional view of various layers of a memory device, in accordance with some embodiments of the present disclosure.

FIGS. 4 and 5 illustrate a layout including device layer and metal layer of an SRAM cell as in FIG. 2, in accordance with some embodiments of the present disclosure.

FIG. 6 illustrates a layout including a metal layer of a logic cell, in accordance with some embodiments of the present disclosure.

FIG. 7 illustrates a layout of active region and metal layer of a portion of a memory macro, in accordance with some embodiments of the present disclosure.

FIG. 8 illustrates a circuit schematic of a CIM circuit including two memory cells, in accordance with some embodiments of the present disclosure.

FIG. 9 illustrates a circuit schematic of a multiplication circuit, in accordance with some embodiments of the present disclosure.

FIG. 10 illustrates a layout of a portion of a memory macro that implements the CIM circuit as in FIG. 8, in accordance with some embodiments of the present disclosure.

FIG. 11 illustrates a circuit schematic of a memory cell including a capacitor as a computational element, in accordance with some embodiments of the present disclosure.

FIG. 12 illustrates a layout of a portion of a memory macro that implements a capacitor as a computational element in each memory cell, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

This disclosure relates generally to in-memory computing systems, referred to as compute-in-memory or computing-in-memory (CIM) systems, and further to integration of memory cells and logic cells for CIM applications. CIM systems store information in the memory, such as in the random-access memory (RAM) of a computer, and perform calculations at the memory cell level, rather than moving large quantities of data between the memory and a processor for each computational step. Since the data is accessed from the memory and processed in the same memory, operations are much quicker, enabling faster reporting and decision-making in business and machine learning applications. Efforts are ongoing to improve the performance of CIM systems.

Artificial intelligence (AI) uses deep learning techniques, where a computer system may be organized as a neural network having a plurality of interconnected processing nodes that enable the analysis of data. Neural networks include multiple layers of computational nodes, where deeper layers perform computations based on results of computations performed by higher layers. Also, in some neural networks, weights are computed and used to perform computations on input data.

AI systems include machine learning systems, where computer algorithms improve automatically through experience and data. The machine learning algorithms build models based on sample data, known as training data, to make predictions or decisions without being explicitly programmed to do so. In these systems, input data is compared to the trained data, i.e., the computational analysis of properties of known data such as the training data. Example systems can be found in the field of object recognition, where the systems analyze the properties of many known images, such as a thousand or more images, to determine patterns that can be used to perform statistical analysis to identify input images/objects. In some embodiments, the AI systems are referred to as convolutional neural networks (CNN).

Machine learning is very computationally intensive, where machine learning neural networks compute weights to perform computations on input data. Machine learning includes computing dot-products and the absolute difference of vectors, which can be computed using multiply-accumulate (MAC) operations performed on data such as the input data and the weights. The computations for large and deep neural networks involve many data elements, such that it is not practical to store the data in processor cache memory that is prohibitively expensive due to the memory sizes and the cost of the cache memory. Also, transferring data between other memory resources, such as RAM and a processor, is very time consuming and becomes a bottleneck for the machine learning system. In addition, as data sets increase in size, the time and energy/power consumed in moving the data ends up being multiples of the time and energy/power used by the processor to perform the computations.

Thus, CIM circuits have been developed for performing neural network computations. CIM circuits perform operations locally within a memory without sending the data to a host processor. This reduces the amount of data transferred between memory and the host processor, which enables higher throughput and performance. Also, the reduction in data transferred reduces energy/power consumed by the system.

In some CIM systems, a memory array includes memory cells (e.g., SRAM cells) that store weight data and logic cells (e.g., standard cells including inventor (INV), AND, OR, NAND, NOR, Flip-flip, SCAN and so on) that provide logic (e.g., input/output (I/O)) functions. During IC design, designers retrieve the required cells from the cell libraries and position them in desired locations. Subsequently, routing is performed to establish connections between the memory cells and logic cells, creating the desired integrated circuit. For example, an SRAM structure generally includes multilayer interconnect structures providing metal tracks (metal lines) for interconnecting power lines and signal lines between the memory cells and logic cells. However, interconnect structures may consist of one set of metal tracks in the memory region and another set of metal tracks in the logic region, and the two sets of metal tracks are generally not aligned and thus not directly connected. Consequently, metal transitions to higher metal layers are needed to electrically connect the metal tracks in the memory region and the logic region. Such transitions increase resistance and capacitance in the interconnect structures, which presents performance, yield, and cost challenges. It has been observed that these higher resistances and/or higher capacitances exhibited by interconnects in advanced IC technology nodes can significantly delay (and, in some situations, prevent) signals from being routed efficiently to and from IC devices, such as transistors, negating any improvements in performance of such IC devices in the advanced technology nodes. Such transitions may be implemented in edge cells inserted between the memory region and the logic region, which also costs valuable real estate area on chip and increases manufacturing cost. Accordingly, the integration of memory cells and logic cells for CIM applications has not been entirely satisfactory in all respects.

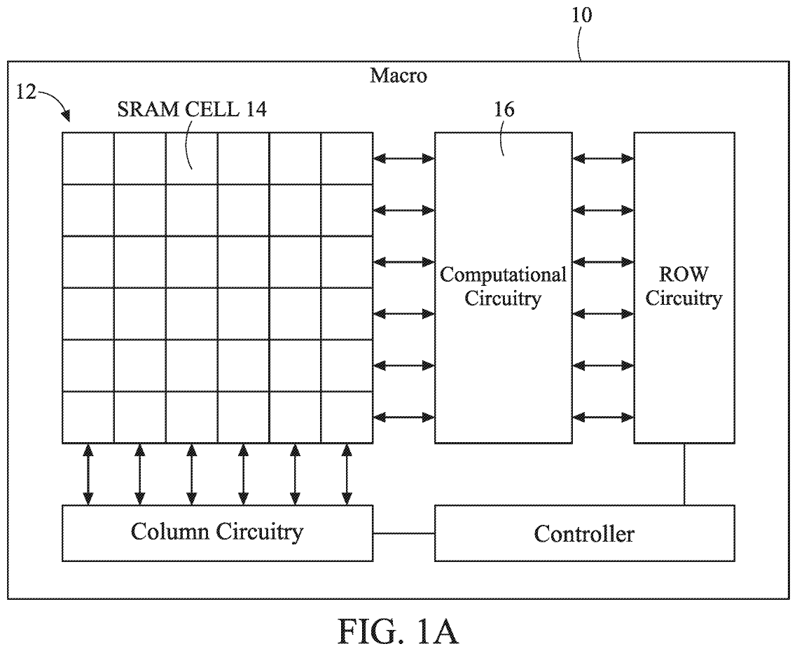

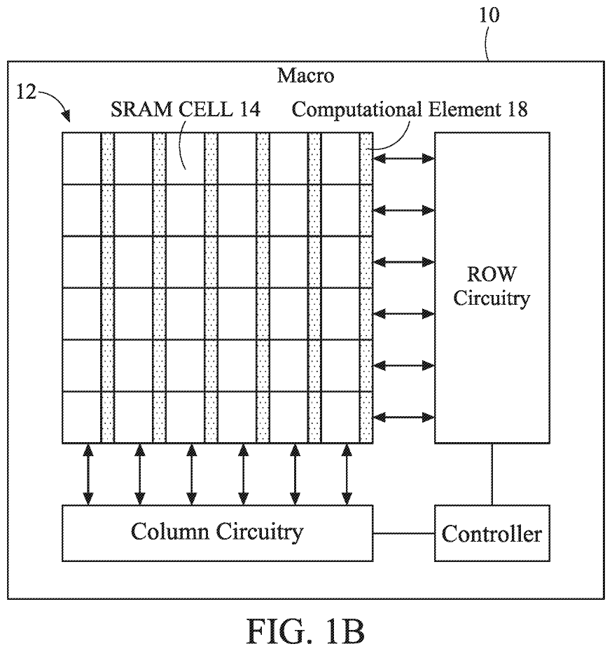

Reference now is made to FIGS. 1A and 1B, which illustrate a circuit macro (hereinafter, macro) 10. The macro 10 may reside in a semiconductor device (or IC). In some embodiments, the macro 10 is a static random-access memory (SRAM) macro, such as a single-port SRAM macro, a dual-port SRAM macro, or other types of SRAM macro. However, the present disclosure contemplates embodiments, where macro 10 is another type of memory, such as a dynamic random-access memory (DRAM), a non-volatile random-access memory (NVRAM), a flash memory, or other suitable memory. FIGS. 1A and 1B have been simplified for the sake of clarity to better understand the inventive concepts of the present disclosure. Additional features can be added in the macro 10, and some of the features described below can be replaced, modified, or eliminated in other embodiments of the macro 10.

In some embodiments, the macro 10 includes memory cells and peripheral circuits. The memory cells are also referred to as bit cells, and are configured to store memory bits. The peripheral cells are also referred to as logic cells that are disposed around the bit cells, and are configured to implement various logic functions. The logic functions of the logic cells include, for example, write and/or read decoding, word line selecting, bit line selecting, data driving and memory self-testing. The logic functions of the logic cells described above are given for the explanation purpose. Various logic functions of the logic cells are within the contemplated scope of the present disclosure.

FIG. 1A illustrates an embodiment of a CIM architecture wherein an SRAM array 12 interfaces with additional computational circuitry to facilitate CIM operations. The SRAM cells 14 are arranged in rows and columns of an array, with each cell capable of storing one bit of data. The row circuitry selects the specific SRAM row for either data retrieval or storage operations, while the column circuitry interfaces with the SRAM columns. The controller coordinates the overall operation of the SRAM array, including the flow of data to and from the computational circuitry. The computational circuitry 16, positioned adjacent to the SRAM array 12, performs operations on the data retrieved from the memory cells, such as multiply-accumulate (MAC) functions, essential for neural network inference tasks. This integration allows for data processing directly within the memory, reducing the need to transfer data between the memory and a separate processor, which enhances speed and efficiency in data-centric applications.

FIG. 1B illustrates another embodiment of a CIM architecture wherein the computational circuitry 16 is further divided into computational elements 18 that are integrated into each SRAM cell 14. This granular integration allows for parallel processing capabilities within the memory array itself, increasing the computational density and efficiency. Each SRAM cell 14 not only stores data but also participates actively in computation, which can significantly accelerate tasks like vector-matrix multiplications commonly used in machine learning applications. The row circuitry, column circuitry, and controller in FIG. 1B maintain their roles in managing the selection of rows and overall operation of the array. However, these peripheral circuits now play an even more important role in facilitating the input and output signals for computation within the SRAM cells. This structural modification enhances the array's ability to perform in-memory computation, making it even more suitable for intensive digital signal processing and in-memory computing tasks.

In the macro 10, transistors in the memory cells and the logic cells may be implemented with various p-type transistors and n-type transistors such as planar transistors or non-planar transistors including various FinFET transistors, GAA transistors, or a combination thereof. GAA transistors refer to transistors having gate electrodes surrounding transistor channels, such as vertically-stacked gate-all-around horizontal nanowire or nanosheet MOSFET devices. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

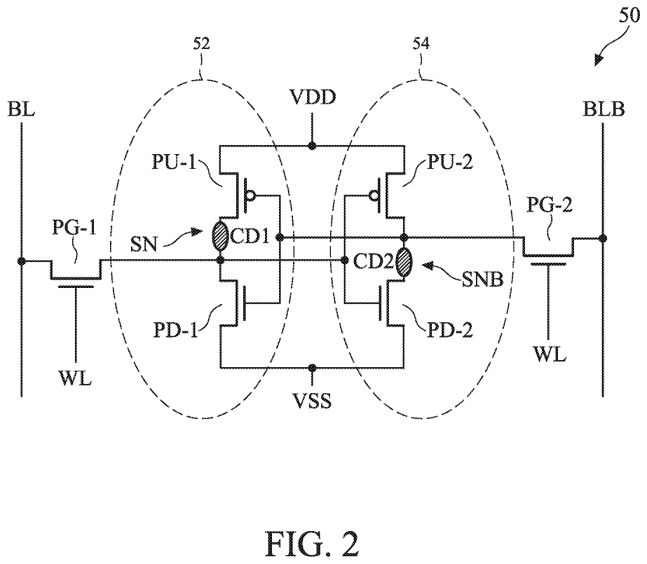

FIG. 2 is a circuit diagram of an exemplary SRAM cell 50, which can be implemented as a memory cell of a SRAM array, according to various aspects of the present disclosure. In some implementations, SRAM cell 50 is implemented as the SRAM cell 14 of the macro 10 (FIG. 1). In the illustrated embodiment, the SRAM cell 50 is a single-port (SP) six-transistor (6T) SRAM cell. In various embodiments, the SRAM cell 50 may be other types of memory cells, such as dual-port memory cell or a memory cell having more than six transistors. FIG. 2 has been simplified for the sake of clarity to better understand the inventive concepts of the present disclosure. Additional features can be added in single-port SRAM cell 50, and some of the features described below can be replaced, modified, or eliminated in other embodiments of single-port SRAM cell 50.

The exemplary SRAM cell 50 is a single port SRAM cell that includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 50, which includes a cross-coupled pair of inverters, an inverter 52 and an inverter 54. The inverter 52 includes the pull-up transistor PU-1 and the pull-down transistor PD-1, and the inverter 54 includes the pull-up transistor PU-2 and the pull-down transistor PD-2. In some implementations, the pull-up transistors PU-1, PU-2 are configured as p-type FinFET transistors or p-type GAA transistors, and the pull-down transistors PD-1, PD-2 are configured as n-type FinFET transistors or n-type GAA transistors.

A gate of the pull-up transistor PU-1 interposes a source (electrically coupled with a power supply voltage (VDD)) and a first common drain (CD1), and a gate of pull-down transistor PD-1 interposes a source (electrically coupled with a power supply voltage (VSS), which may be an electric ground) and the first common drain. A gate of pull-up transistor PU-2 interposes a source (electrically coupled with the power supply voltage (VDD)) and a second common drain (CD2), and a gate of pull-down transistor PD-2 interposes a source (electrically coupled with the power supply voltage (VSS)) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). In the context, the bit line BL and the complementary bit line BLB may also be collectively referred to as bit lines if not separately indicated. The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

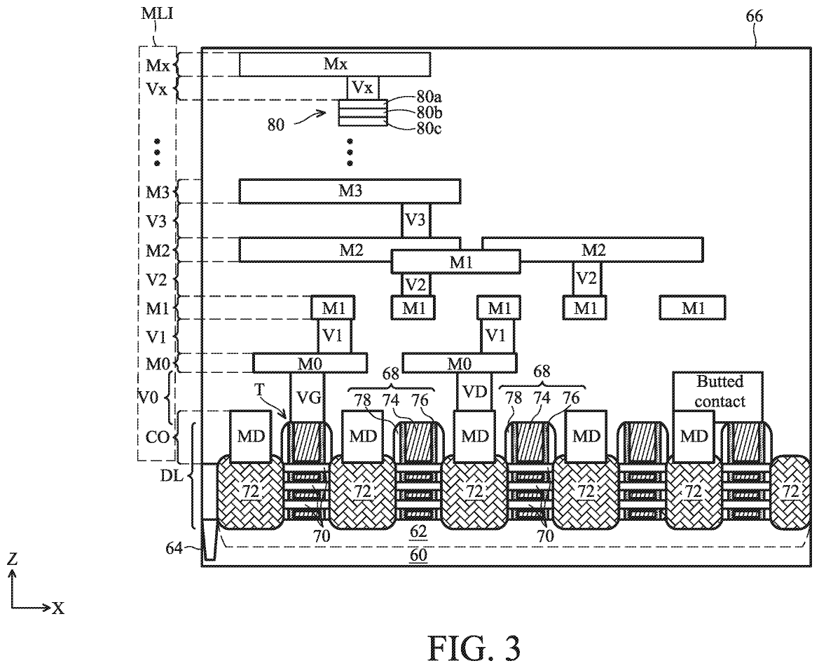

FIG. 3 is a fragmentary diagrammatic cross-sectional view of various layers (levels) that can be fabricated over a semiconductor substrate (or wafer) 60 to form a portion of a memory, such as the macro 10 of FIG. 1, and/or a portion of an SRAM cell, such as SRAM cell 50 of FIG. 2, according to various aspects of the present disclosure. In FIG. 3, the various layers include a device layer DL and a multilayer interconnect MLI disposed over the device layer DL. Device layer DL includes devices (e.g., transistors, resistors, capacitors, and/or inductors) and/or device components (e.g., doped wells, gate structures, and/or source/drain features). In some embodiments, device layer DL includes substrate 60, doped regions 62 disposed in substrate 60 (e.g., n-wells and/or p-wells), isolation features 64, and transistors T. In the depicted embodiment, transistors T include suspended channel layers 70 and gate structures 68 disposed between source/drains 72, where gate structures 68 wrap and/or surround suspended channel layers 70. Each gate structure 68 has a metal gate stack formed from a gate electrode 74 disposed over a gate dielectric 76 and gate spacers 78 disposed along sidewalls of the metal gate stack. Multilayer interconnect MLI electrically couples various devices and/or components of device layer DL, such that the various devices and/or components can operate as specified by design requirements for the memory.

In the depicted embodiment, multilayer interconnect MLI includes a contact layer (CO level), a via zero layer (V0 level), a metal zero (M0) level, a via one layer (V1 level), a metal one layer (M1 level), a via two layer (V2 level), a metal two layer (M2 level), a via three layer (V3 level), a metal three layer (M3 level), and up to a via x layer (Vx level) and a metal x layer (Mx level). The present disclosure contemplates multilayer interconnect MLI having more or less layers and/or levels, for example, a total number of N (e.g., N=x+1) metal layers (levels) of the multilayer interconnect MLI with N as an integer ranging from 2 to 10. Each level of multilayer interconnect MLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of multilayer interconnect MLI, such as M0 level, are formed simultaneously. In some embodiments, conductive features at a same level of multilayer interconnect MLI have top surfaces that are substantially planar with one another and/or bottom surfaces that are substantially planar with one another. CO level includes source/drain contacts (MD) disposed in a dielectric layer 66; V0 level includes gate vias VG, source/drain contact vias VD, and butted contacts disposed in the dielectric layer 66; M0 level includes M0 metal lines disposed in dielectric layer 66, where gate vias VG connect gate structures to M0 metal lines, source/drain vias V0 connect source/drains to M0 metal lines, and butted contacts connect gate structures and source/drains together and to M0 metal lines; V1 level includes V1 vias disposed in the dielectric layer 66, where V1 vias connect M0 metal lines to M1 metal lines; M1 level includes M1 metal lines disposed in the dielectric layer 66; V2 level includes V2 vias disposed in the dielectric layer 66, where V2 vias connect M1 lines to M2 lines; M2 level includes M2 metal lines disposed in the dielectric layer 66; V3 level includes V3 vias disposed in the dielectric layer 66, where V3 vias connect M2 lines to M3 lines; and so on, up to the Vx vias and Mx lines.

In the depicted embodiment, the multilayer interconnect MLI further includes one or more device elements 80 disposed above the transistors T and in electrical connection with the sources or drains 72 of the transistors T through metal lines and vias. In some embodiments, the device element 80 may, for example, be configured as a capacitor, such as a metal-insulator-metal (MIM) capacitor that includes at least a top electrode 80a, a bottom electrode 80c, and a dielectric layer 80b stacked therebetween in one example, or other semiconductor devices. In furtherance of some embodiments, each SRAM cell may have a corresponding MIM capacitor formed within the cell boundary in a top view but suspended above the respective SRAM cell in a cross-sectional view. The device element 80 may be the computational element 18 or a part of the computational element 18 (FIG. 1B) residing in a respective SRAM cell in the CIM system. FIG. 3 has been simplified for the sake of clarity to better understand the inventive concepts of the present disclosure. Additional features can be added in the various layers of the memory, and some of the features described can be replaced, modified, or eliminated in other embodiments of the memory. FIG. 3 is merely an example and may not reflect an actual cross-sectional view of the macro 10 and/or the SRAM cells 50 that is discussed in further detail below.

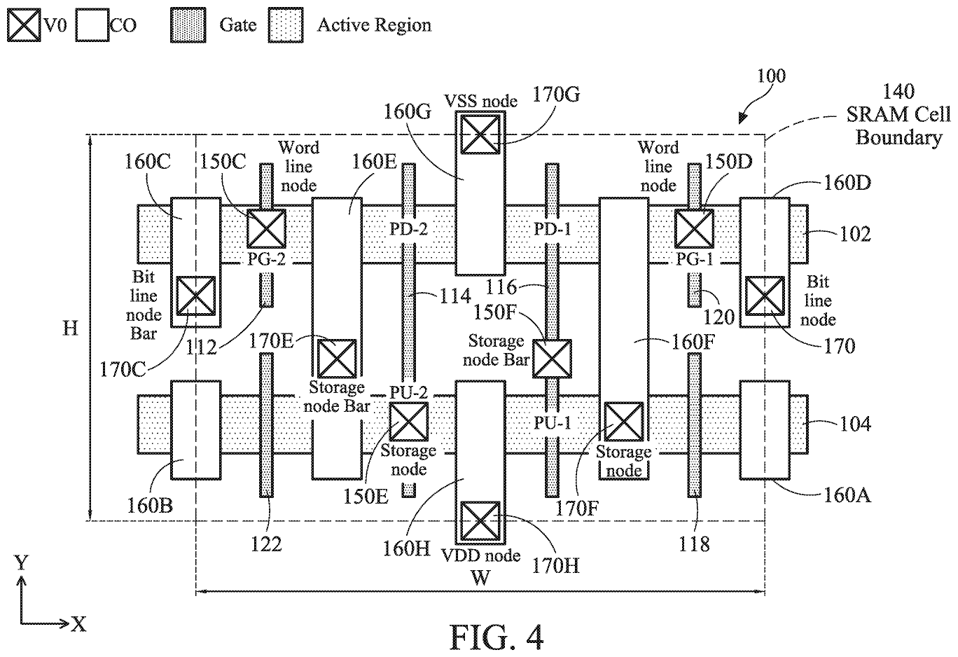

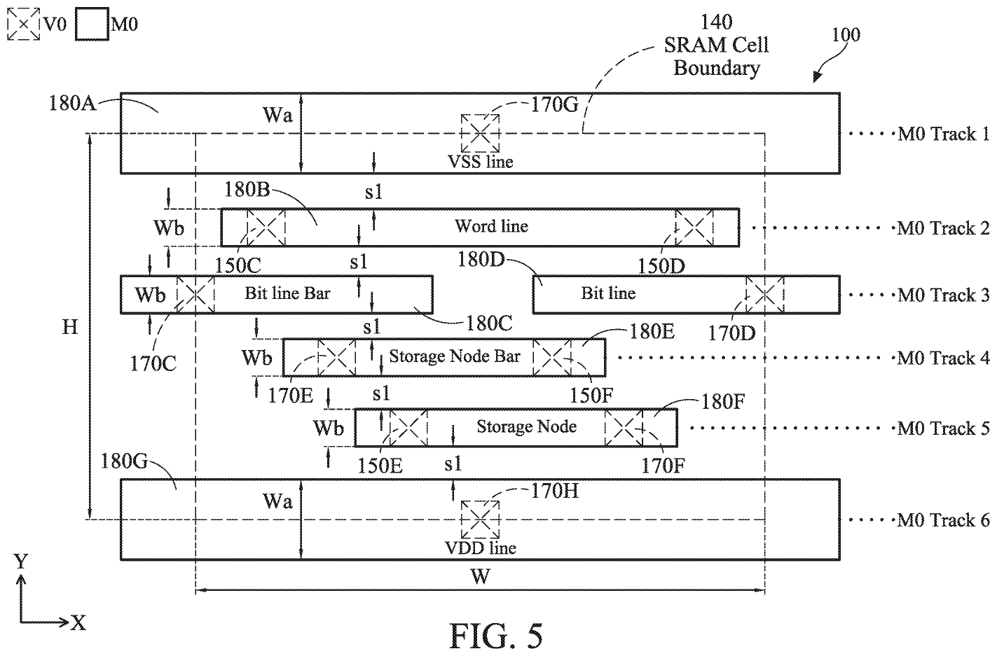

FIGS. 4 and 5 illustrate an exemplary layout 100 of the SRAM cell 50 as in FIG. 2, in which FIG. 4 illustrates the DL level, CO level, and V0 level of the layout 100 and FIG. 5 illustrates V0 level and M0 level of the layout 100. The SRAM cell 50 includes active regions 102 and 104. The active regions 102, 104 each extend lengthwise in the X-direction in FIG. 4. In the illustrated embodiment, the active region 104 belong to the transistors PU-1 and PU-2, which are PMOS devices. As such, the active region 104 is formed over an n-well. Meanwhile, the active region 102 belongs to the transistors PG-1, PD-1, PD-2, PG-2, which are NMOS devices. As such, the active region 102 is formed over a p-well (or a p-type substrate).

The SRAM cell 50 further includes gate structures 112, 114, 116, 118, 120, and 122. The gate structures 112-122 each extend lengthwise in the Y-direction. The gate structures 112 and 120 each extend across the active region 102 to form the transistors PG-2 and PG-1, respectively. The gate structures 114 and 116 each extend across the two active regions 102, 104. As such, the gate structure 114 is shared by the transistors PD-1 and PU-1, and the gate structure 116 is shared by the transistors PD-2 and PU-2. The gate structures 118 and 122 each extend across the active region 104. Yet the gate structures 118 and 122 are non-functional gates, and the transistors formed between the gate structures 118, 122 and the active regions 104 are also non-functional transistors. For example, the gate structures 118 and 122 may remain electrically float or tied to a fixed voltage.

A boundary 140 of the SRAM cell 50 is illustrated using a dashed rectangular box. Note that some of the active regions and gate structures may extend beyond the illustrated boundary 140, since these active regions and gate structures may also form components of other adjacently located SRAM cells as well. The boundary 140 is longer in the X-direction than in the Y-direction. The first dimension of the boundary 140 along the X-direction is denoted as a cell width W, and the second dimension of the boundary 140 along the Y-direction is denoted as a cell height H. Where the SRAM cell 50 is repeated in a memory array, the cell width W may represent and be referred to as a memory cell pitch in the memory array along the X-direction, and the cell height H may represent and be referred to as a memory cell pitch in the memory array along the Y-direction.

The cell size of the SRAM cell 50 is W×H, in which the cell width W is about 4 times a poly pitch (e.g., a center-to-center distance between two adjacent gate structures along the X-direction) and the cell heigh H is about 2 times an isolation pitch (e.g., a center-to-center distance between two adjacent STI features along the Y-direction). Denoting an area of one poly pitch times one isolation pitch as a unit area, each unit area includes an intersection of a gate structure and an active region, and the SRAM cell 50 utilizes a cell size of about 8 times a unit area in accommodating six functional transistors, namely the transistors PG-1, PG-2, PU-1, PU-2, PD-1, and PD-2.

A gate contact 150C electrically connects a gate of the pass-gate transistor PG-2 (formed by the gate structure 112) to the word line node (WL). A gate contact 150D electrically connects a gate of the pass-gate transistor PG-1 (formed by the gate structure 120) to the word line node (WL). A gate contact 150E electrically connects a gate of the pull-down transistor PD-2 (formed by the gate structure 114) and a gate of the pull-up transistor PU-2 (also formed by the gate structure 114) to the storage node (SN). A gate contact 150F electrically connects a gate of the pull-down transistor PD-1 (formed by the gate structure 116) and a gate of the pull-up transistor PU-1 (also formed by the gate structure 116) to the complementary storage node (SNB).

A source/drain contact 160A and a source/drain contact 160B each land on source/drain regions of the non-functional transistors and stay electrically floating, as there is no corresponding source/drain contact vias landing thereon. A source/drain contact 160C and a source/drain contact via 170C landing thereon electrically connect a source region of the pass-gate transistor PG-2 to the complementary bit line node (BLB). A source/drain contact 160D and a source/drain contact via 170D landing thereon electrically connect a source region of the pass-gate transistor PG-1 to the bit line node (BL). A source/drain contact 160E and a source/drain contact via 170E landing thereon electrically connect a common drain region of the pass-gate transistor PG-2 and the pull-down transistor PD-2 together with a drain region of the pull-up transistor PU-2 to the complementary storage node (SNB). A source/drain contact 160F and a source/drain contact via 170F landing thereon electrically connect a common drain region of the pass-gate transistor PG-1 and the pull-down transistor PD-1 together with a drain region of the pull-up transistor PU-1 to the storage node (SN). A source/drain contact 160G and a source/drain contact via 170G landing thereon electrically connect a common source region of the pull-down transistor PD-1 and the pull-down transistor PD-2 to the electrical ground node VSS. A source/drain contact 160H and a source/drain contact via 170H landing thereon electrically connect a common source region of the write-port pull-up transistor PU-1 and the write-port pull-up transistor PU-2 to the power voltage node VDD. In the illustrated embodiment, the source/drain contacts each are elongated and have a longitudinal direction in the Y-direction, which is parallel to the extending directions of gate structures.

The storage node SN includes the gate contact 150E and the source/drain contact via 170F positioned on two opposing sides of the gate structure 116. As to discuss in further detail below, a metal line at the M0 level extends in the X-direction to across the gate structure 116 and connects the gate contact 150E and the source/drain contact via 170F. In other words, an M0 metal line hangs over the gate structure 116 and provide the function of cross coupling between the gate contact 150E and the source/drain contact via 170F. Therefore, in the layout 100, the gate contact 150E and the source/drain contact via 170F are positioned as being level in the Y-direction, such that a metal line extending in the X-direction may connect both. Similarly, the complementary storage node (storage node bar) SNB includes the gate contact 150F and the source/drain contact via 170E positioned on two opposing sides of the gate structure 114. As to discuss in further detail below, another metal line at the M0 level extends in the X-direction to across the gate structure 114 and connects the gate contact 150F and the source/drain contact via 170E. In other words, another M0 metal line hangs over the gate structure 114 and provide the function of cross coupling between the gate contact 150F and the source/drain contact via 170E. Therefore, in the layout 100, the gate contact 150F and the source/drain contact via 170E are positioned as being level in the Y-direction, such that a metal line extending in the X-direction may connect both.

FIG. 5 illustrates the V0 level and M0 level of the layout 100 of the metal interconnect structures of the SRAM cell 50. At the M0 level, the SRAM cell 50 includes a plurality of metal tracks arranged in parallel. Particularly, in the illustrated embodiment of the layout 100, the SRAM cell 50 includes six metal tracks arranged in order from first (M0 Track 1) to sixth (M0 Track 6) along the Y-direction. The center lines of the metal tracks are represented by the dotted lines in FIG. 5.

In the layout 100, the first metal track “M0 Track 1” includes a global metal line 180A, which is a VSS line electrically coupled to the source/drain contact via 170G. The term “global metal line” refers to the metal line traveling through the entire SRAM cell 50 along the X-direction. Otherwise, the metal line is termed a “local metal line.” The VSS line 180A is disposed on an upper edge of the SRAM cell 50 and may be shared with an adjacent SRAM cell. The second metal track “M0 Track 2” includes a local metal line 180B as a landing pad for the word line (WL). The local metal line 180B is fully within the SRAM cell 50 and electrically connects to the gate contact 150C and the gate contact 150D. The third metal track “M0 Track 3” includes two local metal lines 180C and 180D. The local metal line 180C provides a landing pad for the complimentary bit line (BLB). The local metal line 180C extends beyond a left edge of the SRAM cell 50 and may be shared with an adjacent SRAM cell. The local metal line 180D provides a landing pad for the bit line (BL). The local metal line 180D extends beyond a right edge of the SRAM cell 50 and may be shared with an adjacent SRAM cell. The fourth metal track “M0 Track 4” includes a local metal line 180E. The local metal line 180E is fully within the SRAM cell 50, which belongs to the complementary storage node (SNB) and provides cross-coupling between the gate contact 150F and the source/drain contact via 170E. As discussed above, the local metal line 180E crosses over the gate structure 114. The fifth metal track “M0 Track 5” includes a local metal line 180F. The local metal line 180F is fully within the SRAM cell 50, which belongs to the storage node (SN) and provides cross-coupling between the gate contact 150E and the source/drain contact via 170F. As discussed above, the local metal line 180F crosses over the gate structure 116. The sixth metal track “M0 Track 6” includes a global metal line 180G, which is a VDD line electrically coupled to the source/drain contact via 170H. The VDD line 180G is disposed on a lower edge of the SRAM cell 50 and may be shared with an adjacent SRAM cell.

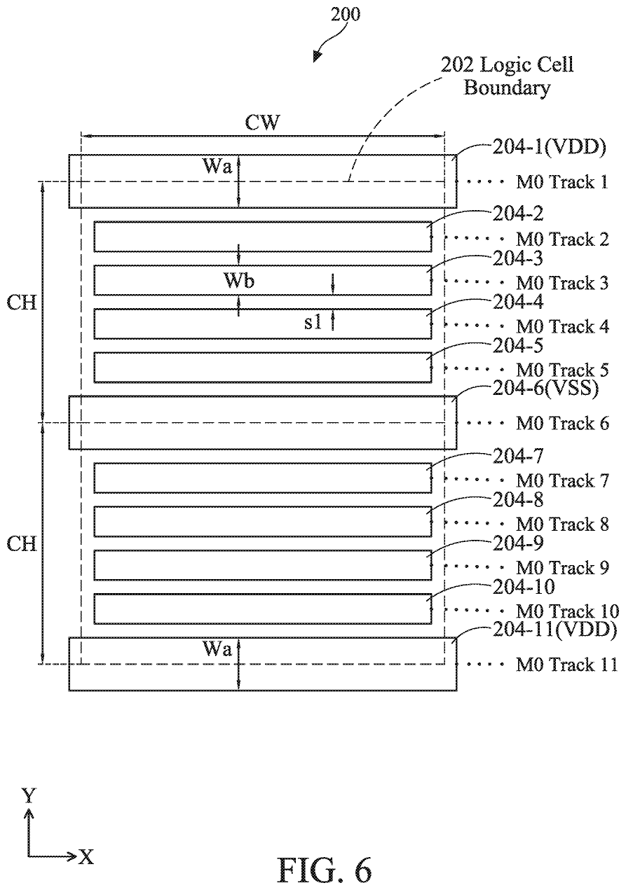

A width of the VSS line 180A is denoted as Wa with one half of Wa in one SRAM cell and another half of Wa in the adjacent SRAM cell. A width of the VDD line 180G may be substantially the same as the VSS line 180A with one half of Wa in one SRAM cell and another half of Wa in the adjacent SRAM cell. The other M0 metal lines 180B-180F may each have the same width denoted as Wb. The spacing between two adjacent M0 metal lines may be uniform and denoted as S1. Thus, the SRAM cell height H equals Wa+4*Wb+5*S1. The layout 100 of the SRAM cell 50 has a cell height H corresponding to six metal tracks. As discussed in further detail below, the SRAM cell 50 and the logic cell as shown in FIG. 6 may have the same cell height, allowing each SRAM cell 50 to directly abut a single logic cell.

The SRAM cell 50 may be fabricated in the same memory macro (such as the macro 10 in FIG. 1) with a logic cell (often referred to as a standard cell). In such embodiments, metal lines in the M0 level of the SRAM cell 50 and metal lines in the M0 level of the logic cell can be configured to optimize both SRAM performance and logic density (co-optimization). For example, FIG. 6 is a layout 200 of metal lines in the M0 level of two logic cells arranged in the Y-direction, according to various aspects of the present disclosure. Each of the logic cell has a cell boundary 202 represented by a dashed rectangular box. The cell boundary 202 has a first dimension, such as a cell width CW, along a first direction (e.g., X-direction) and a second dimension, such as a cell height CH, along a second direction (e.g., Y-direction).

The M0 level of the logic cells includes metal lines electrically connected to a device layer. The device layer of the logic cell includes transistors, such as n-type transistors and p-type transistors, each of which has a gate disposed between a source and a drain, where M0 level of the logic cells is electrically connected to at least one gate, at least one source, and/or at least one drain of the transistors. In some embodiments, gates of the transistors of the logic cells extend longitudinally along the same direction as gates in the SRAM cell 50, and metal lines of M0 layer of the logic cell have a routing direction that is substantially perpendicular to the gate lengthwise direction. In some embodiments, the two abutting logic cells have a total of 2*N+1 (an odd number) metal lines arranged in the Y-direction, where N is an integer. In the illustrated embodiment, N equals 5, and the two abutting logic cells have eleven metal lines, namely metal lines 204-1 through 204-11. In various other embodiments, N may equal integers other than 5, such as 4 or 6. In some embodiments, the two abutting logic cells may functionally be considered as one logic cell having a cell height H and a cell width CW and having 2*N+1 metal lines.

The metal lines at the M0 level each may be arranged in a respective metal track. At the M0 level, the SRAM structure may include a plurality of metal tracks arranged in parallel (e.g., from Track 1 to Track 2*N+1). In the illustrated embodiment of the layout 200, the logic cells include eleven metal tracks arranged in order from first (M0 Track 1) to 11^{th} (M0 Track 11) along the Y-direction. The center lines of the metal tracks are represented by the dashed lines in FIG. 6.

In the illustrated embodiment, the center metal track (the (N+1)^{th} metal track, or the M0 Track 6 in FIG. 6) includes a metal line (e.g., the metal line 204-6 in FIG. 6) devoted as a VSS line. The metal track positioned as the second one away from the middle metal track (the (N−1)^{th} metal track or the (N+3)^{th} metal track, or the M0 Track 4 or the M0 Track 8 in FIG. 6) includes a metal line (e.g., the metal line 204-4 or the metal line 204-8 in FIG. 6) devoted to a signal line that is coupled to the SRAM cell 50, which is either a bit line BL or a bit line bar BLB. The metal tracks positioned as the first and the last metal tracks (1^{st} and (2*N+1)^{th} metal tracks, or the M0 Track 1 and the M0 Track 11 in FIG. 6) each include a metal line (e.g., the metal line 204-1 and the metal line 204-11 in FIG. 6) devoted as the VDD line.

As depicted, the metal lines at the M0 level are evenly distributed along the Y-direction with the spacing S1. A width of the VDD line 204-1 (and 204-11) is Wa. A width of the VSS line 204-6 may be substantially the same as the VDD line 204-1 (and 204-11) as Wa. The other M0 metal lines may each have the same width Wb. Thus, the logic cell height CH equals Wa+4*Wb+5*S1, which is the same as the SRAM cell height H (i.e., H=CH), such that each logic cell may abut a respective SRAM cell 50 with M0 metal tracks and corresponding M0 metal lines in the logic cell and the SRAM cell 50 align.

In some memory structures, metal tracks (and respective metal lines) in the SRAM cells and the logic cells are not aligned. One solution is to implement one or more edge cells positioned between the SRAM cells and the logic cells. Inside the edge cells, metal transitions are provided to electrically couple metal lines at the M0 level to other metal lines in higher metal layers (e.g., M1 level and/or M2 level) to implement a bridge to connect the signal lines in the SRAM cells and the logic cells. However, such metal transitions increase routing resistance and parasitic capacitance to the already resistance and capacitance sensitive signal lines, thereby undesirably increasing RC delay and decreasing SRAM speed, for example, write/read speed. Insertion of the edge cells also creates waste of the already valuable layout space. In the illustrated embodiments as depicted in FIGS. 5 and 6 collectively, the metal tracks (and respective metal lines) in the SRAM cells 50 and the logic cells are aligned, such a configuration allows the signal lines and power lines to directly extend from the logic cells into the SRAM cells 50 without a need for extra metal transitions. The direct metal line connections reduce routing resistance and parasitic capacitance, which simplifies circuit layout, improves circuit speed, and increases layout space utilization.

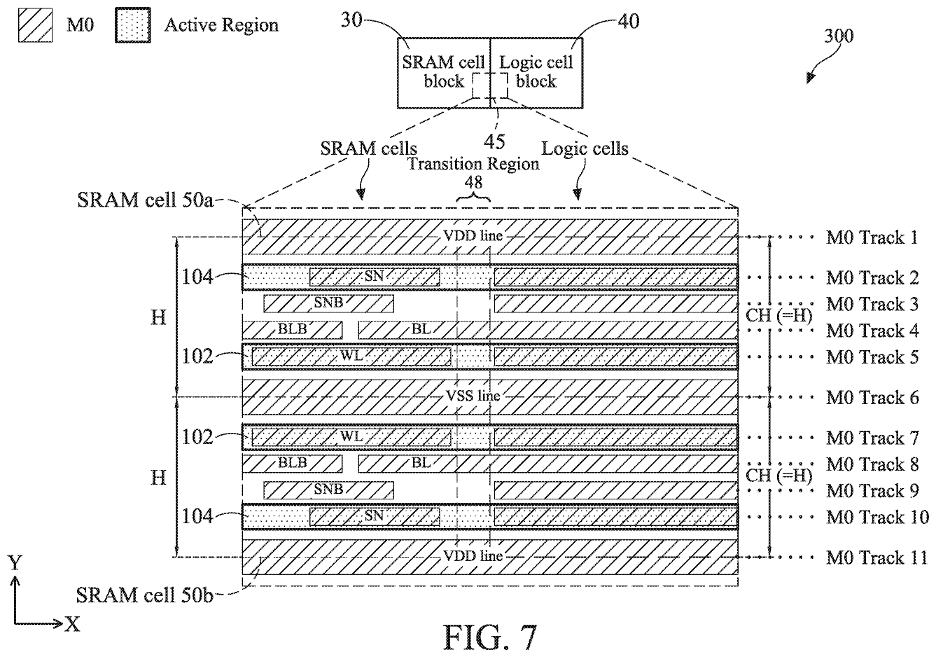

FIG. 7 illustrates the DL level and V0 level of a layout 300 of a circuit region 45 in the macro 10 (FIG. 1), which includes a portion of the SRAM cell block 30 and a portion of the logic cell block 40 and extends across an interface between the SRAM cell block 30 and the logic cell block 40. The SRAM cell block 30 may be a portion of the SRAM array 12 (FIG. 1), and the logic cell block 40 may be a portion of the peripheral circuits, such as row circuitry, column circuitry, and controller (FIG. 1). FIG. 7 has been simplified for the sake of clarity to better understand the inventive concepts of the present disclosure. For example, only active regions in the DL level and metal lines at the V0 level are shown, while numerous other features such as gate structures, contacts, and vias are omitted in FIG. 7.

As discussed above, the SRAM cells 50 and the logic cells may have the same cell height (H=CH). FIG. 7 depicts a column of two SRAM cells, in which a first SRAM cell 50a abutting a first logic cell and a second SRAM cell 50b abutting a second logic cell. The two adjacent SRAM cells 50a and 50b are line symmetric with respect to a common boundary therebetween. That is, the second SRAM cell 50b is a duplicate cell for the SRAM cell 50a but flipped over the X-axis;

The active regions 102 and 104 in the SRAM cell block 30 are oriented lengthwise in the X-direction and evenly distributed along the Y-direction. The active regions in the logic cell block 40 are also oriented lengthwise in the X-direction and evenly distributed along the Y-direction. Further, the active regions in the SRAM cell block 30 and the logic cell block 40 have the same width and spacing. Therefore, the active regions in the SRAM cell block 30 and the logic cell block 40 can be aligned. Still further, in the illustrated embodiment, the active regions extend through the interface between the SRAM cell block 30 and the logic cell block 40. In other words, the transistors in the SRAM cell block 30 and the logic cell block 40 may share the same continuous active regions.

The metal tracks in the SRAM cell block 30 are also aligned with the metal tracks in the logic cell block 40, allowing the metal lines in the logic cells to extend into the SRAM cells. Thus, there is no need for edge cells between the SRAM cell block 30 and the logic cell block 40 to provide metal transitions for the metal lines at the M0 level. The M0 Track 1 includes a VDD line extending through the first SRAM cell 50a and the first logic cell. The M0 Track 2 includes a local metal line for SN inside the first SRAM cell 50a and a signal line inside the first logic cell. The M0 Track 3 includes a local metal line for SNB inside the first SRAM cell 50a and a signal line inside the first logic cell. The M0 Track 4 includes a local metal line for BLB in the first SRAM cell 50a, and a signal line in the first logic cell that extends into the first SRAM cell 50a and merges with the metal line for BL in the first SRAM cell 50a. The M0 Track 5 includes a local metal line for WL inside the first SRAM cell 50a and a signal line inside the first logic cell. The M0 Track 6 includes a VSS line extending through the first/second SRAM cells and first/second logic cells. The M0 Track 7 includes a local metal line for WL inside the second SRAM cell 50b and a signal line inside the second logic cell. The M0 Track 8 includes a local metal line for BLB in the second SRAM cell 50b, and a signal line in the second logic cell that extends into the second SRAM cell 50b and merges with the metal line for BL in the second SRAM cell 50b. The M0 Track 9 includes a local metal line for SNB inside the second SRAM cell 50b and a signal line inside the second logic cell. The M0 Track 10 includes a local metal line for SN inside the second SRAM cell 50b and a signal line inside the second logic cell. The M0 Track 11 includes a VDD line extending through the second SRAM cell 50b and the second logic cell.

Between the opposing boundary lines of the SRAM cells in the SRAM cell block 30 and the logic cells in the logic cell block 40 is an active region transition region 48, or simply as the transition region 48. Inside the transition region 48, the active regions shared by the SRAM cells and the corresponding logic cells in the same row travel through.

Gate structures (not shown in FIG. 7) for the SRAM cells and the logic cells are oriented along the Y-direction and evenly distributed along the X-direction with a uniform distance between two adjacent gate structures. The uniform distance is denoted as a gate pitch or a poly pitch (“PP”). The transition region 48 may have a width of two gate pitches along the X-direction in one embodiment. Other widths are possible. For example, the transition region 48 may have a width of three, four, five, six, seven, eight, or even more gate pitches along the X-direction in other embodiments.

The gate structures intersect the active regions 102 and 104 in forming transistors. Transistors formed at the intersections of the active regions 102 and 104 and the gate structures within the SRAM cell block 30 are devoted to form SRAM cells. Transistors formed at the intersections of the active regions 102 and 104 and the gate structures within the logic cell block 40 are devoted to form logic cells. Transistors are also formed at the intersections of the active regions 102 and 104 and the gate structures inside the transition region 48. Due to the alignment of the metal tracks (and respective metal lines) in the SRAM cells and the logic cells, the transition region 48 does not need to host edge cells. Therefore, the transistors formed inside the transition region 48 may be utilized as functional transistors other than non-functional transistors to improve circuit area utilization. For example, the transistors formed inside the transition region 48 may be implemented as the computational circuitry 16 or a portion of the computational circuitry 16 (FIG. 1A) for CIM applications.

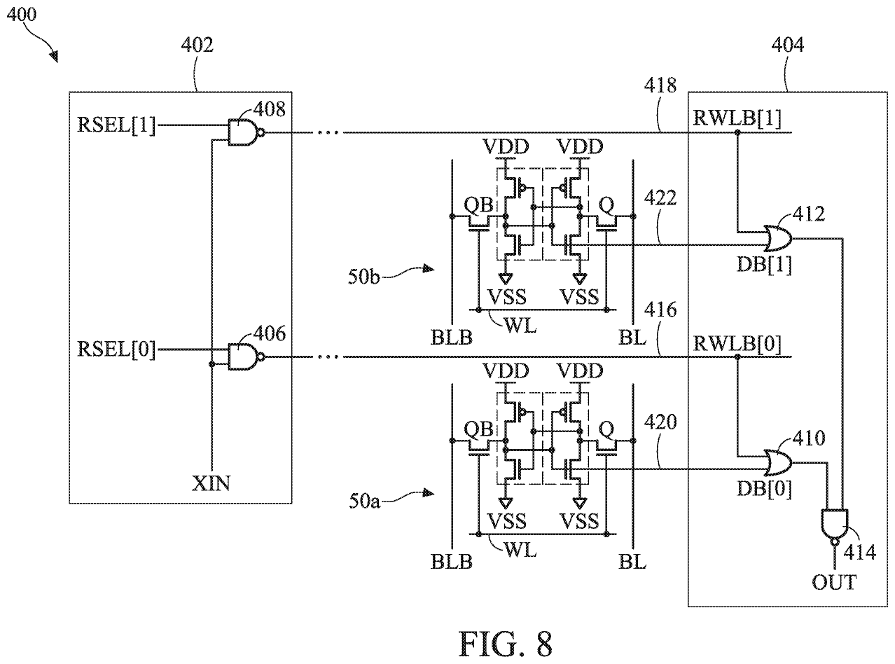

FIG. 8 is a diagram schematically illustrating a portion of a CIM circuit 400 configured to multiply input data XIN and data from the SRAM cells 50a and 50b, in accordance with some embodiments. The CIM circuit 400 includes the SRAM cells 50a and 50b, a word line driver 402, and a multiplication circuit 404. The word line driver 402 includes NAND gates 406 and 408 that are electrically coupled to the multiplication circuit 404. Each of the NAND gates 406 and 408 is configured to receive the input signal XIN and one of the read select signals RSEL[0] and RSEL[1]. Also, each of the NAND gates 406 and 408 is configured to provide one of the read word line signals RWLB[0] and RWLB[1] to the multiplication circuit 404 to activate a selected row of the SRAM cells 50a and 50b. NAND gate 406 receives the input signal XIN and the read select signal RSEL[0] and provides read word line signal RWLB[0] to the multiplication circuit 404. NAND gate 408 receives the input signal XIN and the read select signal RSEL[1] and provides read word line signal RWLB [1] to the multiplication circuit 404.

The SRAM cells 50a and 50b are electrically coupled to the multiplication circuit 404 to provide stored bits of data to the multiplication circuit 404 in the data signals DB[0] and DB[1]. In some embodiments, the SRAM cells 50a and 50b are configured to store weight data, such as weights for a convolutional neural network (CNN).

The multiplication circuit 404 includes logic gates for multiplying the input data signal XIN that is received from the word line driver 402 and bits of data from the SRAM cells 50a and 50b. In this example, the multiplication circuit 404 includes a first OR gate 410, a second OR gate 412, and a NAND gate 414. In other embodiments the multiplication circuit 404 includes different logic gates. The first OR gate 410 is configured to receive the read word line signal RWLB[0] from the word line driver 402 and the data signal DB[0] from the SRAM cell 50a. The second OR gate 412 is configured to receive the read word line signal RWLB[1] from the word line driver 402 and the data signal DB[1] from the SRAM cell 50b. The NAND gate 414 receives an output from each of the first and second OR gates 410 and 412 and provides the result of the multiplication at output OUT.

In operation, to select one of the SRAM cells 50a and 50b, one of the NAND gates 406 and 408 in the word line driver 402 receives a logic high (1) read select signal RSEL[0] or RSEL[1] and the other one of the NAND gates 406 and 408 receives a logic low (0) read select signal RSEL[0] or RSEL[1]. The NAND gate 406 or 408 that receives the logic low (0) read select signal RSEL[0] or RSEL[1] is not selected and provides a logic high (1) to one of the OR gates 410 or 412, which passes the logic high (1) to one input of the output NAND gate 414. The NAND gate 406 or 408 that receives the logic high (1) read select signal RSEL[0] or RSEL[1] is selected to invert the input signal XIN and pass the inverted input signal XINB to the other one of the OR gates 410 or 412. The OR gate 410 or 412 that receives the inverted input signal XINB also receives one of the data signals DB[0] or DB[1] from the connected SRAM cell 50a or 50b and provides an output signal to the other input of the output NAND gate 414. This multiplies the inverted input signal XINB and the data received from the connected SRAM cell 50a or 50b. The NAND gate 414 provides the multiplication result at the output OUT.

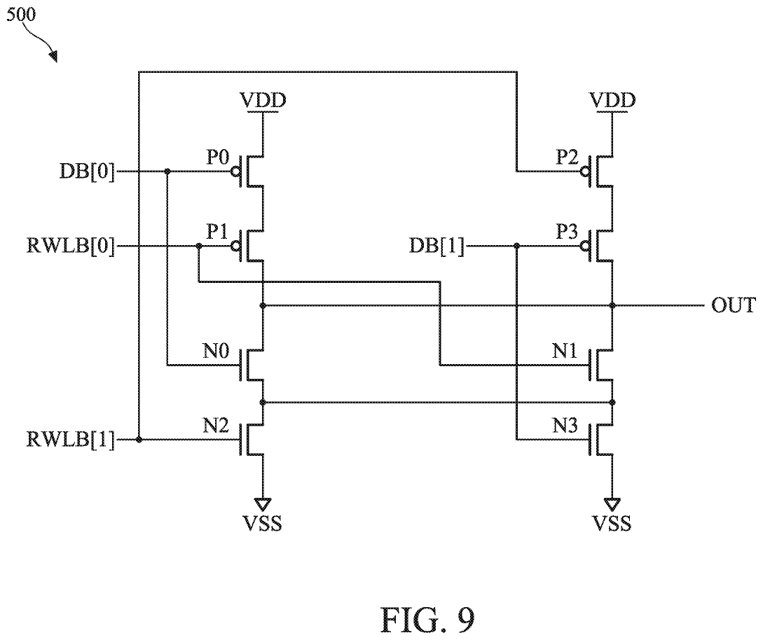

FIG. 9 is a diagram schematically illustrating a computational circuitry 500 that provides the functions of the multiplication circuit 404 (FIG. 8), in accordance with some embodiments. The computational circuitry 500 includes eight transistors, four PMOS transistors P0, P1, P2, and P3 and four NMOS transistors N0, N1, N2, and N3. A first S/D of PMOS transistor P0 is electrically coupled to power VDD, and a second S/D of PMOS transistor P0 is electrically coupled to a first S/D of PMOS transistor P1. Also, a first S/D of PMOS transistor P2 is electrically coupled to power VDD and a second S/D of PMOS transistor P2 is electrically coupled to a first S/D of PMOS transistor P3. The second S/D of PMOS transistor P1 is electrically coupled to the second S/D of PMOS transistor P3 and to a first S/D of each of the NMOS transistors N0 and N1. The second S/D of NMOS transistor N0 is electrically coupled to the second S/D of NMOS transistor N1 and to a first S/D of each of the NMOS transistors N2 and N3. The second S/D of each of the NMOS transistors N2 and N3 is electrically coupled to a reference VSS, such as ground. The gates of PMOS transistor P0 and NMOS transistor N0 are electrically coupled together to receive the data signal DB[0], and the gates of PMOS transistor P3 and NMOS transistor N3 are electrically coupled together to receive the data signal DB[1]. Also, the gates of PMOS transistor P1 and NMOS transistor N1 are electrically coupled together to receive the read word line signal RWLB[0] and the gates of PMOS transistor P2 and NMOS transistor N2 are electrically coupled together to receive the read word line signal RWLB[1].

In operation, if the read word line signal RWLB[1] is at a logic low (0), the PMOS transistor P2 is biased on and the NMOS transistor N2 is biased off. Also, if the read word line signal RWLB[0] is at a logic high (1), the PMOS transistor P1 is biased off and the NMOS transistor N1 is biased on. Thus, if data signal DB[1] is at a logic low (0), the PMOS transistor P3 is biased on and the NMOS transistor N3 is biased off, such that the output OUT is at a logic high (1), and if data signal DB[1] is at a logic high (1), the PMOS transistor P3 is biased off and the NMOS transistor N3 is biased on, such that the output OUT is at a logic low (0). Also, if the read word line signal RWLB[0] is at a logic low (0), the PMOS transistor P1 is biased on and the NMOS transistor N1 is biased off, and if the read word line signal RWLB[1] is at a logic high (1), the PMOS transistor P2 is biased off and the NMOS transistor N2 is biased on. Thus, if data signal DB[0] is at a logic low (0), the PMOS transistor P0 is biased on and the NMOS transistor NO is biased off, such that the output OUT is at a logic high (1), and if data signal DB[0] is at a logic high (1), the PMOS transistor P0 is biased off and the NMOS transistor 270 is biased on, such that the output OUT is at a logic low (0). If each of the read word line signal RWLB[0] and the read word line signal RWLB[1] is at a logic high (1), the PMOS transistors P1 and P2 are biased off and the NMOS transistors N2 and N1 are biased on, such that the output OUT is at a logic low (0).

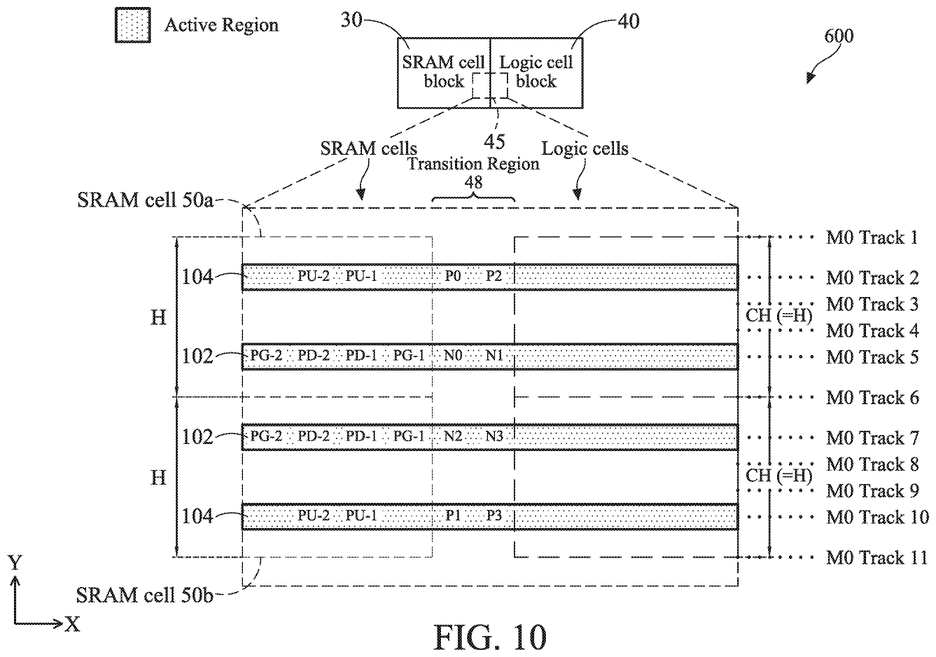

FIG. 10 illustrates a layout 600 of the circuit region 45 similar to the layout 300 (FIG. 7) with one difference being the implementation of the computational circuitry 500 (FIG. 9) in the transition region 48. FIG. 10 has been simplified for the sake of clarity to better understand the inventive concepts of the present disclosure. For example, only active regions in the DL level are shown, while numerous other features such as gate structures, contacts, vias, and metal lines are omitted in FIG. 10. As discussed above, due to the alignment of the metal tracks (and respective metal lines) in the SRAM cells and the logic cells, the transition region 48 does not need to host edge cells. Therefore, the transistors formed inside the transition region 48 may be utilized as functional transistors other than non-functional transistors to improve circuit utilization. In the illustrated embodiment, PMOS transistors P0 and P2 are formed on the portion of the continuous active region 104 extending from the first SRAM cell 50a and located in the transition region 48; NMOS transistors N0 and N1 are formed on the portion of the continuous active region 102 extending from the first SRAM cell 50a and located in the transition region 48; NMOS transistors N2 and N3 are formed on the portion of the continuous active region 102 extending from the second SRAM cell 50b and located in the transition region 48; and PMOS transistors P1 and P3 are formed on the portion of the continuous active region 104 extending from the second SRAM cell 50b and located in the transition region 48. The computational circuitry 500 that provides the functions of a multiplication circuit is merely an example. The computational circuitry 500 may be implemented to provide other functions, such as accumulations, sum of absolute difference, and other computational functions suitable for CIM applications. The implementation of computational circuitry in the transition region between SRAM and logic cells simplifies circuit complexity, thereby reducing circuit area. This also minimizes data movement distance, consequently improving device speed and reducing power requirements.

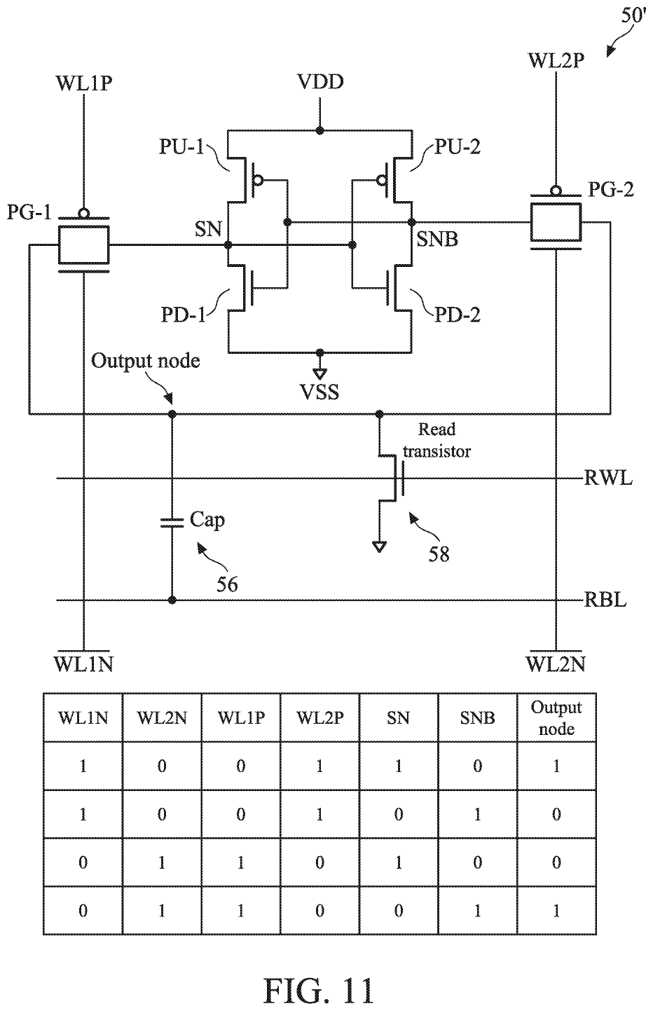

As discussed above with reference to FIG. 1B, computational circuitry may be further divided into computational elements that are integrated into each SRAM cell. FIG. 11 illustrates an exemplary SRAM cell 50′ that implements an XNOR logic inside the cell. The SRAM cell 50′ is also referred to as XNOR bit cell. The SRAM cell 50′ is integrated with an internal capacitor 56 between the bit cell and a read bit line. The SRAM cell 50′ includes similar elements as the SRAM cell 50 (FIG. 2) with differences that the capacitor 56 is coupled between the bit cell output node and the first read bit line RBL, the read transistor 58 is coupled to the bit cell and the first read word line RWL, and PG-1 and PG-2 are implemented as transmission gates with control signals WL1P, WL1N and control signals WL2P, WL2N, respectively. In this configuration within a CIM bit cell array, the first read word line RWL on the selected column is turned on to discharge any voltage remaining on the internal capacitor 56, P channel transmission gate on PG-1 or PG-2 is turned on depends on data 1 or 0 and desired data state is written into the bit cell. A truth table is provided in FIG. 5 as well to illustrate the logic function of the SRAM cell 50′ as an XNOR bit cell.

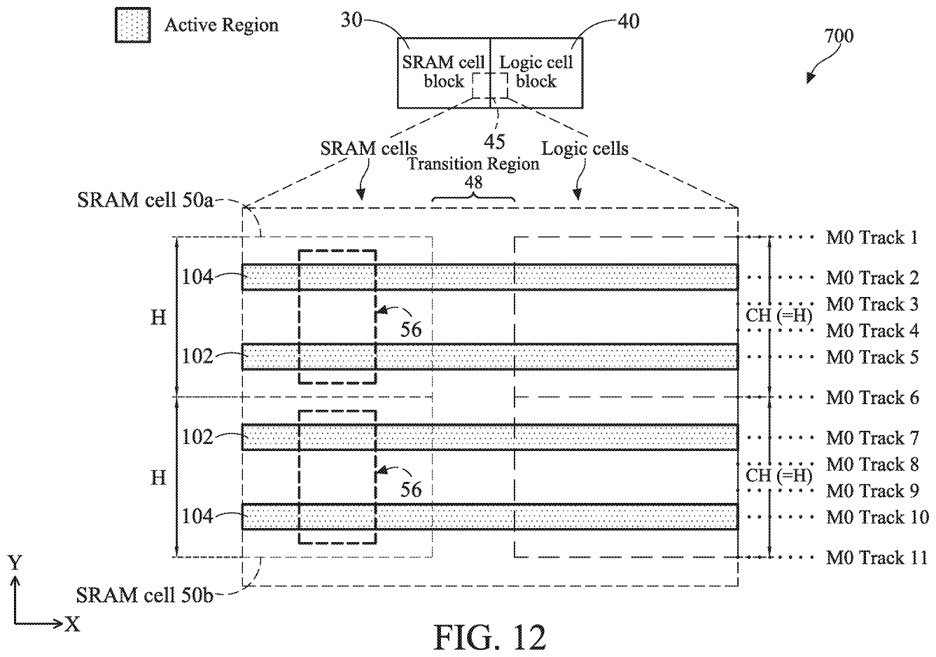

FIG. 12 illustrates a layout 700 of the circuit region 45 similar to the layout 300 (FIG. 7) or the layout 500 (FIG. 10) with one difference being the implementation of the capacitor 56 inside the cell boundary of each SRAM cell 50′ from a top view. FIG. 12 has been simplified for the sake of clarity to better understand the inventive concepts of the present disclosure. For example, only active regions in the DL level are shown, while numerous other features such as gate structures, contacts, vias, and metal lines are omitted in FIG. 12. The capacitor 56 may be implemented as a metal-insulator-metal (MIM) capacitor that resides in higher metal layers (e.g., M4 level or above) suspended above each SRAM cell 50. The capacitor 56 may be implemented as the device element 80 as shown in FIG. 3. In the depicted embodiment, a contour of the capacitor 56 in a top view is represented by a dashed rectangular box extending lengthwise in the Y-direction and overlapping with both the active regions 102 and 104. In various other embodiments, the contour of the capacitor 56 in a top view may have other shapes, such as a square or a circle, and may overlap with only one of the active regions, or stacked between the two active regions along the Y-direction with no overlapping. Further, similar to the layout 500 (FIG. 10), the transition region 48 may include functional transistors formed on the active regions 102 and 104 and electrically coupled to the capacitor 56 and/or the transistors in the SRAM cell 50′.

Based on the above discussions, it can be seen that the present disclosure offers advantages over conventional semiconductor structures. It is understood, however, that other embodiments may offer additional advantages, and not all advantages are necessarily disclosed herein, and that no particular advantage is required for all embodiments. For example, the present disclosure provides a memory macro that is suitable for implementing CIM systems or other memory systems. The memory macro provides an integration of memory cells and logic cells, which allows memory cells and logic cells closely arranged to each other and having active regions and metal tracks (and metal lines) aligned. Computational circuitry can be implemented in a transition region between the memory cells and the logic cells, which allows data to be analyzed in real time, enabling faster reporting and decision-making in CIM applications with reduced circuit complexity, reduced circuit area, improved circuit speed, and reduced power requirements.

In one exemplary aspect, the present disclosure is directed to a semiconductor structure. The semiconductor structure includes a memory cell connected to a signal line, a first voltage line for receiving a power supply voltage, and a second voltage line for receiving an electric ground voltage, a logic cell configured to provide logic function to the memory cell, the logic cell being connected to the signal line, the first voltage line, and the second voltage line, a transition region extending from a first boundary of the memory cell to a second boundary of the logic cell, and an interconnect structure disposed over the memory cell and the logic cell. The interconnect structure includes the signal line, the first voltage line, and the second voltage line located in a same metal line layer of the interconnect structure. The signal line extends from inside the second boundary of the logic cell and into the first boundary of the memory cell. The transition region includes one or more functional transistors electrically coupled to the memory cell. In some embodiments, the memory cell is a static random-access memory (SRAM) cell. In some embodiments, the one or more functional transistors in the transition region are electrically coupled to the logic cell. In some embodiments, the signal line is a bit line. In some embodiments, the signal line is a bit line bar. In some embodiments, the first boundary of the memory cell has a first width, the second boundary of the logic cell has a second width, and the first width equals the second width. In some embodiments, the memory cell includes an active region extending continuously along a first direction through the transition region and into the logic cell. In some embodiments, at least one of the one or more functional transistors in the transition region is formed on the active region. In some embodiments, the first and second voltage lines overlap with first and second edges of the first boundary of the memory cell, respectively, the first and second edges opposing each other, and the first and second voltage lines overlap with third and fourth edges of the second boundary of the logic cell, respectively, the third and fourth edges opposing each other. In some embodiments, the metal line layer of the interconnect structure is a lowest metal line layer of the interconnect structure.

In another exemplary aspect, the present disclosure is directed to a semiconductor structure. The semiconductor structure includes a memory cell having a first boundary, a logic cell having a second boundary, and an interconnect structure disposed over the memory cell and the logic cell. The interconnect structure includes a signal line extending continuously along a first direction from inside the second boundary of the logic cell and into the first boundary of the memory cell, and a computational element disposed within the first boundary of the memory cell in a top view of the semiconductor structure and suspended above the signal line in a cross-sectional view of the semiconductor structure. In some embodiments, the computational element is a metal-insulator-metal (MIM) capacitor. In some embodiments, the computational element is electrically coupled to an output node of the memory cell. In some embodiments, the memory cell includes first and second active regions each extending continuously along the first direction from inside the first boundary of the memory cell and into the second boundary of the logic cell. In some embodiments, a contour of the computational element overlaps with the first and second active regions from the top view of the semiconductor structure. In some embodiments, a contour of the computational element is free of overlapping with the first and second active regions from the top view of the semiconductor structure. In some embodiments, the semiconductor structure further includes a transition region stacked between the memory cell and the logic cell along the first direction. The transition region includes functional transistors electrically coupled to the memory cell.

In yet another exemplary aspect, the present disclosure is directed to a semiconductor structure. The semiconductor structure includes a six-transistor static random-access memory (6T-SRAM) cell having a plurality of first metal tracks in parallel, and a logic cell having a plurality of second metal tracks in parallel. A number of the first metal tracks equals a number of the second metal tracks. Each of the first metal tracks is aligned with one of the second metal tracks. One of the second metal tracks includes a signal line that extends into the 6T-SRAM cell. In some embodiments, the signal line is a bit line. In some embodiments, the 6T-SRAM cell includes first and second active regions each extending continuously into the logic cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a memory cell connected to a signal line, a first voltage line for receiving a power supply voltage, and a second voltage line for receiving an electric ground voltage;
a logic cell configured to provide logic function to the memory cell, wherein the logic cell is connected to the signal line, the first voltage line, and the second voltage line;
a transition region extending from a first boundary of the memory cell to a second boundary of the logic cell; and
an interconnect structure disposed over the memory cell and the logic cell,
wherein the interconnect structure includes the signal line, the first voltage line, and the second voltage line located in a same metal line layer of the interconnect structure,
wherein the signal line extends from inside the second boundary of the logic cell and into the first boundary of the memory cell, and
wherein the transition region includes one or more functional transistors electrically coupled to the memory cell.

2. The semiconductor structure of claim 1, wherein the memory cell is a static random-access memory (SRAM) cell.

3. The semiconductor structure of claim 1, wherein the one or more functional transistors in the transition region are electrically coupled to the logic cell.

4. The semiconductor structure of claim 1, wherein the signal line is a bit line.

5. The semiconductor structure of claim 1, wherein the signal line is a bit line bar.

6. The semiconductor structure of claim 1, wherein the first boundary of the memory cell has a first width, the second boundary of the logic cell has a second width, and the first width equals the second width.

7. The semiconductor structure of claim 1, wherein the memory cell includes an active region extending continuously along a first direction through the transition region and into the logic cell.

8. The semiconductor structure of claim 7, wherein at least one of the one or more functional transistors in the transition region is formed on the active region.

9. The semiconductor structure of claim 1, wherein the first and second voltage lines overlap with first and second edges of the first boundary of the memory cell, respectively, the first and second edges opposing each other, and
wherein the first and second voltage lines overlap with third and fourth edges of the second boundary of the logic cell, respectively, the third and fourth edges opposing each other.

10. The semiconductor structure of claim 1, wherein the metal line layer of the interconnect structure is a lowest metal line layer of the interconnect structure.

11. A semiconductor structure, comprising:
a memory cell having a first boundary;
a logic cell having a second boundary; and
an interconnect structure disposed over the memory cell and the logic cell,
wherein the interconnect structure includes:
a signal line extending continuously along a first direction from inside the second boundary of the logic cell and into the first boundary of the memory cell, and
a computational element disposed within the first boundary of the memory cell in a top view of the semiconductor structure and suspended above the signal line in a cross-sectional view of the semiconductor structure.

12. The semiconductor structure of claim 11, wherein the computational element is a metal-insulator-metal (MIM) capacitor.

13. The semiconductor structure of claim 11, wherein the computational element is electrically coupled to an output node of the memory cell.

14. The semiconductor structure of claim 11, wherein the memory cell includes first and second active regions each extending continuously along the first direction from inside the first boundary of the memory cell and into the second boundary of the logic cell.

15. The semiconductor structure of claim 14, wherein a contour of the computational element overlaps with the first and second active regions from the top view of the semiconductor structure.

16. The semiconductor structure of claim 14, wherein a contour of the computational element is free of overlapping with the first and second active regions from the top view of the semiconductor structure.

17. The semiconductor structure of claim 11, further comprising:
a transition region stacked between the memory cell and the logic cell along the first direction, wherein the transition region includes functional transistors electrically coupled to the memory cell.

18. A semiconductor structure, comprising:
a six-transistor static random-access memory (6T-SRAM) cell having a plurality of first metal tracks in parallel; and
a logic cell having a plurality of second metal tracks in parallel,
wherein:
a number of the first metal tracks equals a number of the second metal tracks,
each of the first metal tracks is aligned with one of the second metal tracks, and
one of the second metal tracks includes a signal line that extends into the 6T-SRAM cell.

19. The semiconductor structure of claim 18, wherein the signal line is a bit line.

20. The semiconductor structure of claim 18, wherein the 6T-SRAM cell includes first and second active regions each extending continuously into the logic cell.
